(19) United States
(12) Patent Application Publication
(10) Pub. No.: US 2024/0113116 A1
(43) Pub. Date: Apr. 4, 2024

(54) EPITAXIAL STRUCTURE AND GATE METAL STRUCTURES WITH A PLANAR TOP SURFACE

(71) Applicant: Intel Corporation, Santa Clara, CA (US)

(72) Inventors: Dan S. LAVRIC, Beaverton, OR (US); YenTing CHIU, Portland, OR (US); Tahir GHANI, Portland, OR (US); Leonard P. GULER, Hillsboro, OR (US); Mohammad HASAN, Aloha, OR (US); Aryan NAVABI-SHIRAZI, Portland, OR (US); Anand S. MURTHY, Portland, OR (US); Wonil CHUNG, Hillsboro, OR (US); Allen B. GARDINER, Portland, OR (US)

(21) Appl. No.: 17/958,293

(22) Filed: Sep. 30, 2022

(51) Int. Cl. H01L 27/092; H01L 21/02; H01L 21/8238; H01L 29/06; H01L 29/423; H01L 29/49; H01L 29/66; H01L 29/775

(52) U.S. Cl. CPC H01L 27/092; H01L 21/02603; H01L 21/823807; H01L 21/823842; H01L 29/0673; H01L 29/42392; H01L 29/4908; H01L 29/66439; H01L 29/775

(57) ABSTRACT

Embodiments described herein may be related to apparatuses, processes, systems, and/or techniques for integrated circuit structures that include self-aligned metal gates, self-aligned epitaxial structure, self-aligned terminal contacts over the epitaxial structure, and removal of poly material around a gate during integrated circuit structure manufacture, using a tub gate architecture. Other embodiments may be described and/or claimed.

### FIELD

Embodiments of the present disclosure generally relate to the field of semiconductor manufacturing, and in particular to manufacturing transistor structures.

### BACKGROUND

Continued growth in virtual machines, cloud computing, and portable devices will continue to increase the demand for high density transistors within chips and packages. In addition, there will be an increased need for high quality transistor structure components within these chips and packages.

### BRIEF DESCRIPTION OF THE DRAWINGS

FIG. 1 illustrates a top-down and various cross-section side views of integrated circuit structures within a tub gate architecture that have self-aligned metal gates and self-aligned epitaxial structure, in accordance with various embodiments.

FIGS. 2A-2J illustrate cross-section side views of stages in a manufacturing process for creating a self-aligned metal gate fill pattern within a tub gate architecture, in accordance with various embodiments.

FIGS. 3A-3P illustrate cross-section side views of stages in a manufacturing process for creating a self-aligned epitaxial structure source/drain within a tub gate architecture, in accordance with various embodiments.

FIGS. 4A-4E illustrate cross-section side views of stages in a manufacturing process for creating a terminal connector (TCN) on a self-aligned epitaxial structure source/drain within a tub gate architecture, in accordance with various embodiments.

FIG. 5A-5N illustrate cross-section side views of stages in a manufacturing process for performing poly silicon removal using an isotropic etch within a tub gate architecture.

FIG. 6 illustrates an example process for manufacturing of integrated circuit structures within a tub gate architecture that include aligned self-aligned metal gates, in accordance with various embodiments.

FIG. 7 illustrates a computing device in accordance with one implementation of the invention.

FIG. 8 illustrates an interposer that includes one or more embodiments of the invention.

### DETAILED DESCRIPTION

Embodiments described herein may be related to apparatuses, processes, systems, and/or techniques for creating integrated circuit structures that include self-aligned metal gates, self-aligned epitaxial structure, self-aligned TCN over the epitaxial structure, and removal of poly silicon material around a gate during integrated circuit structure manufacture, using a tub gate architecture. In embodiments, a tub gate architecture includes a plurality of walls, which may be referred to as tub walls, that are orthogonal to a plurality of gate spacers. In embodiments, each section of an integrated circuit structure that is bounded by two gate spacers and two tub walls may be referred to as a tub.

In embodiments, a first tub may include a gate metal with a vertical stack of nanoribbons running through the gate metal, where the gate metal may be entirely within the tub. In embodiments, a second tub may be next to the first tub and share a portion of the gate spacer, where the second tub includes an epitaxial structure within the second tub that may serve as a source or a drain with respect to the gate in the first tub. In embodiments, the second tub may include an N-type epitaxial structure or a P-type epitaxial structure.

In other embodiments, a third tub may be next to the first tub and share a portion of a wall. The third tub may include a gate metal with a vertical stack of nanoribbons running through the gate metal. In embodiments, the first tub may include an N-type metal and the third tub may include a P-type metal. Embodiments herein described various manufacturing techniques, including self-aligned techniques, may be used to efficiently form N-type gates that are next to P-type gates, and may be used to efficiently form N-type epitaxial structure that are next to P-type epitaxial structure within the tub architecture. In still other embodiments, the tub architecture may be used to facilitate poly silicon removal during the manufacturing process of a plurality of gates.

Embodiments described herein may be shown with respect to a nanoribbon transistor architectures, however embodiments are also applicable to finFET or forkFET transistor architectures, as well as other transistor architectures.

In the following detailed description, reference is made to the accompanying drawings which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

Various operations may be described as multiple discrete operations in turn, in a manner that is most helpful in understanding the claimed subject matter. However, the order of description should not be construed as to imply that these operations are necessarily order dependent.

As used herein, the term “module” may refer to, be part of, or include an ASIC, an electronic circuit, a processor (shared, dedicated, or group) and/or memory (shared, dedicated, or group) that execute one or more software or firmware programs, a combinational logic circuit, and/or other suitable components that provide the described functionality.

Various Figures herein may depict one or more layers of one or more package assemblies. The layers depicted herein are depicted as examples of relative positions of the layers of the different package assemblies. The layers are depicted for the purposes of explanation, and are not drawn to scale. Therefore, comparative sizes of layers should not be assumed from the Figures, and sizes, thicknesses, or dimensions may be assumed for some embodiments only where specifically indicated or discussed.

Various embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

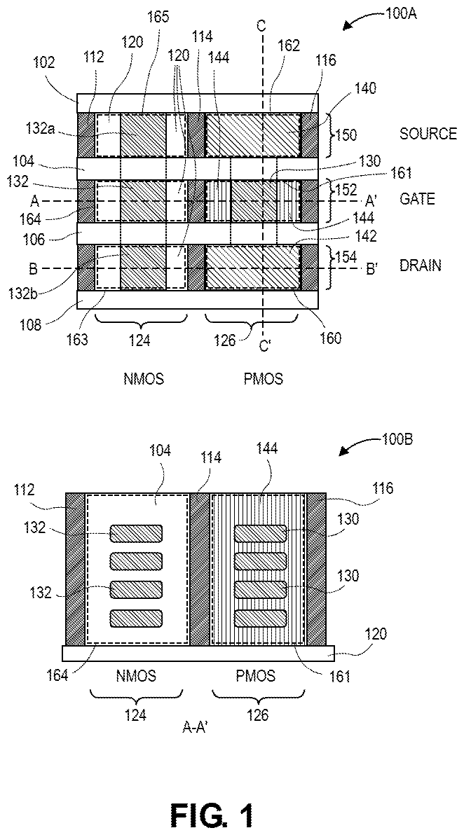

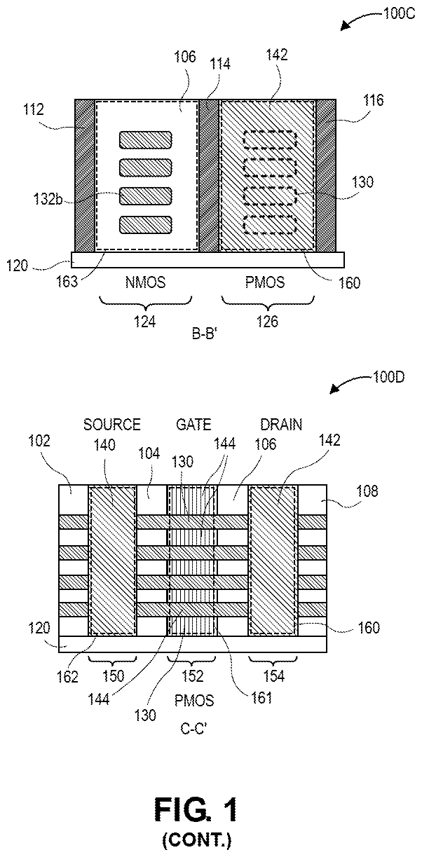

FIG. 1 illustrates a top-down view and various cross-section side views of integrated circuit structures within a tub gate architecture that have self-aligned metal gates and self-aligned epitaxial structure, in accordance with various embodiments. Integrated circuit structure 100A shows a top-down view that includes an NMOS portion 124 and a PMOS portion 126 that are next to each other, and are separated by a first wall 114. A second wall 112 may be to the left of the NMOS portion 124, and a third wall 116 may be to the right of the PMOS portion 126. In embodiments, the first wall 114, second wall 112, and third wall 116 may be referred to as tub walls, and may extend to a bottom layer 120 as shown in diagram 100B. In embodiments, the walls 114, 112, 116 may include silicon, nitrogen, carbon, oxygen, hafnium, SinN, SiC, SiON, SiCN, HfO and/or HfN.

In embodiments, the NMOS portion 124 and the PMOS portion 126 may be further divided into a source region 150 between spacers 102, 104, a gate region 152 between spacers 104, 106, and a drain region 154 between spacers 106, 108. In embodiments, the spacers 102, 104, 106, 108 extend to the bottom layer 120 as shown in diagram 100D. As a result six tubs 160, 161, 162, 163, 164, 165 are formed, each surrounded on five sides by the bottom layer 120, and one or more of the first wall 114, second wall 112, third wall 116, and/or spacers 102, 104, 106, 108. In embodiments, this configuration may be referred to as a tub architecture.

In embodiments, each tub 160, 161, 162, 163, 164, 165 may have chemistry applied to create various structures or to apply various etching processes as described further below, without necessarily affecting the structures or chemistry of an adjacent tub. Embodiments described herein may include various apparatus including transistor structures, integrated circuit structures, semiconductor devices, as well as various techniques and processes that may be used in conjunction with the tub architecture.

Tubs 160, 161, 162 show embodiments that have been fully manufactured. Tub 161, which is part of the gate region 152 within the PMOS portion 126, includes a stack of nanoribbons 130 that are surrounded by a gate metal 144. In embodiments, the gate metal 144 may include P-type metal. In embodiments, the stack of nanoribbons 130 extend into the spacer 104 and into the spacer 106. Tub 162, which is part of a source region 150 within the PMOS portion 126, includes an epitaxial structure 140. In embodiments, the epitaxial structure 140 may be a Boron Doped epitaxial structure Si—Ge (P-EPI). Ends of the stack of nanoribbons 130 may be physically coupled with the epitaxial structure 140. Tub 160, which is part of the drain region 154 within PMOS portion 126, includes an epitaxial structure 142. In embodiments, the epitaxial structure 142 may be a Boron Doped epitaxial structure Si—Ge (P-EPI). Ends of the stack of nanoribbons 130 may be physically coupled with the epitaxial structure 142.

Tubs 163, 164 165 show embodiments that are partially manufactured. Tub 164, which is part of the gate region 152 within the NMOS portion 124, shown a stack of nanoribbons 132 that extend between and into spacer 104 and spacer 106. As shown, the stack of nanoribbons 132 have not yet been surrounded by a gate metal. Tub 165, which is part of the source region 150 within the NMOS portion 124, show a stack of nanoribbons 132a, which may be continuations of nanoribbons 132, that extend from the spacer 104 to the spacer 102. As shown, the stack of nanoribbons 132a have not yet been etched and the tub 165 has not yet been filled with an epitaxial structure material. Tub 163, which is part of the drain region 154 and the NMOS portion 124, show a stack of nanoribbons 132b, which may be continuations of nanoribbons 132, that extend from the spacer 106 to the spacer 108. As shown, the stack of nanoribbons 132b have not yet been etched and the tub 163 has not yet been filled with an epitaxial structure material.

Diagram 100B shows a cross-section side view of integrated circuit structure 100A at A-A′, within the gate region 152 that shows walls 112, 114, 116, bottom layer 120, and spacer 104 that form a portion of tub 164 within NMOS region 124 and tub 161 within PMOS region 126. The stack of nanoribbons 132 within tub 164 are not surrounded by any gate metal, and the stack of nanoribbons 130 within the tub 161 are surrounded by gate metal 144, which may include a P-type metal.

Diagram 100C shows a cross-section side view of integrated circuit structure 100A at B-B′, within drain region 154, that shows walls 112, 114, 116, bottom layer 120, and spacer 106 that form a portion of tub 163 within NMOS region 124 and form a portion of tub 160 within PMOS region 126. The stack of nanoribbons 132b within tub 163 are not yet etched and replaced with an epitaxial structure. An epitaxial structure 142 is placed within tub 160, and adjacent to stack of nanoribbons 130 that are within spacer 106.

Diagram 100D shows a cross-section side view of an integrated circuit structure 100A at C-C′, within PMOS region 126. Spacers 102, 104, 106, 108, and bottom layer 120 form a portion of tubs 162, 161, 160. Tub 161, within the gate region 152, includes the stack of nanoribbons 130, that extend into spacers 104, 106, are surrounded by gate metal 144. Tub 162, within source region 150, is filled with epitaxial structure 140 which is physically coupled with ends of the stack of nanoribbons 130 in spacer 104. Tub 160, within drain region 154, is filled with an epitaxial structure 142 which is physically coupled with ends of the stack of nanoribbons 130 in spacer 106.

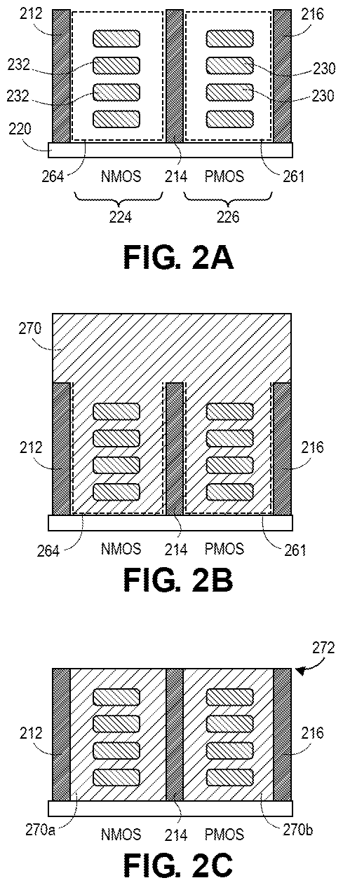

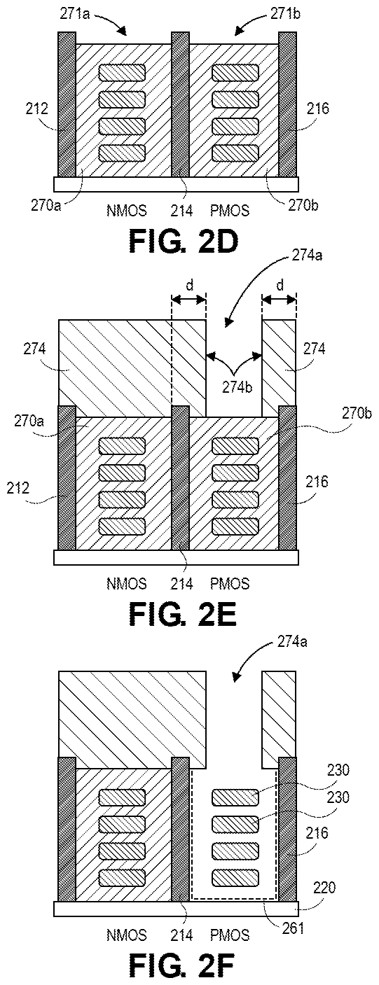

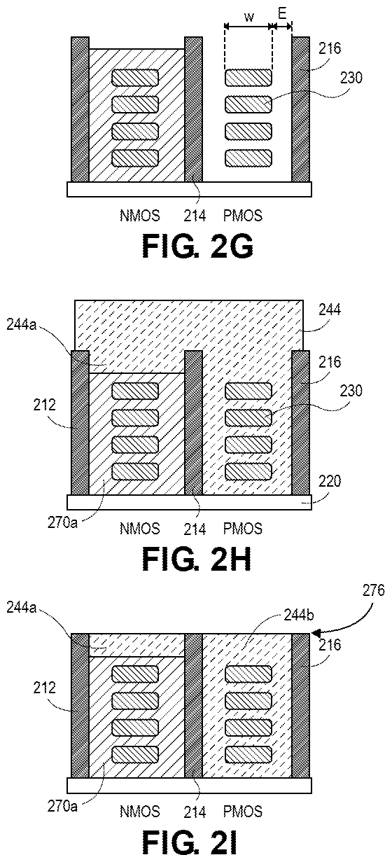

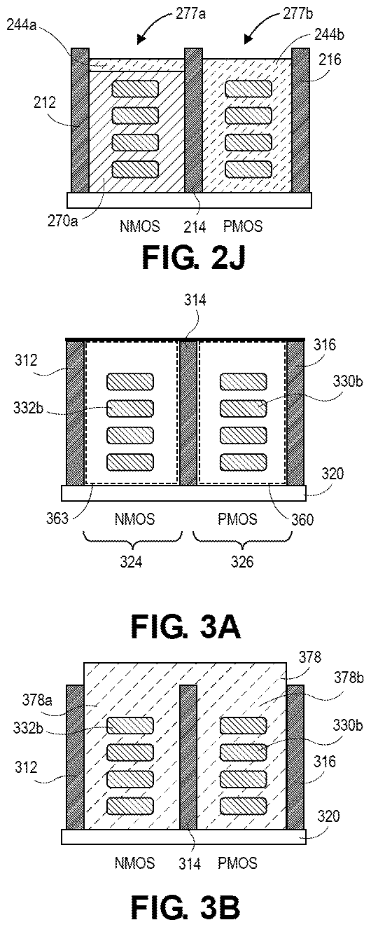

FIGS. 2A-2J illustrate cross-section side views of stages in a manufacturing process for creating a self-aligned metal gate fill pattern within a tub gate architecture, in accordance with various embodiments.

In legacy implementations, metal gate patterning using legacy transistor architecture stacks up WFM of opposite polarity that create non-uniform threshold voltage (Vt) at tight gate endcaps. These legacy implementations use atomic layer deposition (ALD) Vt Adjust (VTA) layers of a WFM polarity that stack on top of each other, creating different VTA thicknesses in different NMOS or PMOS devices. In legacy implementations, a final WFM stack is achieved by blanket deposition of a thick ALD WFM of opposite polarity on top of the stacked VTA. In these legacy implementations, multi-Vt is obtained by the thick WFM shining through the various stacked VTA thicknesses of opposite polarity. However, in these legacy implementations, tight gate end caps, for example less than 6-8 nm, do not provide enough room for the thick WFM of opposite polarity to get deposited on the legacy stack of VTA. As a result, in legacy implementations, there is no thick WFM shining through anymore, and Vt is non-uniform for the channel facing the tight gate end cap.

Turning back now to embodiments, FIG. 2A shows a cross-section side view, which may be similar to cross-section side view A-A′ of integrated circuit structure 100A and diagram 100B of FIG. 1, of a stage in the manufacturing process that includes a bottom layer 220, and walls 212, 214, 216 that form tub 264 in NMOS region 224 and form tub 261 in PMOS region 226, which may be similar to bottom layer 120, walls 112, 114, 116, tubs 164, 161, NMOS region 124, and PMOS region 126 of FIG. 1. In embodiments, tub 264 includes a stack of nanoribbons 232, and tub 261 includes a stack of nanoribbons 230, which may be similar to stack of nanoribbons 132, 130 of FIG. 1. Note that the stack of nanoribbons 232, 230 are not surrounded by any gate metal.

FIG. 2B shows a cross-section side view of a stage in the manufacturing process where an N-type WFM 270 is placed into the tubs 264, 261, and also extends above the walls 212, 214, 216. In embodiments, this may be referred to as NMOS saturation.

FIG. 2C shows a cross-section side view of a stage in the manufacturing process where a planarization occurs to produce surface 272 where a top of the walls 212, 214, 216 and a top of the N-type WFM 270a and top of the N-type WFM 270b are in a plane. In embodiments, the planarization may be performed using chemical metal polishing (CMP).

FIG. 2D shows a cross-section side view of a stage in the manufacturing process where an etching process may be performed to produce recess 271a in the N-type WFM 270a, and recess 271b in the N-type WFM 270b. In embodiments, a dry etch process may be used. In embodiments, the recesses 271a, 271b may be below a top of the walls 212, 214, 216.

FIG. 2E shows a cross-section side view of a stage in the manufacturing process where a mask 274 is placed above the N-type WFM 270a, N-type WFM 270b, and walls 212, 214, 216, and into the recesses 271a, 271b of FIG. 2D. In embodiments, the mask 274 may be a carbon hard mask. After the mask 274 is placed, an opening 274a is made into the mask 274 to expose the N-type WFM 270b. In embodiments, edges 274b of the opening 274a may be placed at a distance “d” away from a side of the walls 214, 216. In embodiments, this distance “d” may be greater than or equal to an edge placement error (EPE) value known in the manufacturing process. In these embodiments, the distance “d” may be chosen so that the N-type WFM 270a will be sealed by the mask 274 and the walls 212, 214 allowing for known manufacturing variations.

FIG. 2F shows a cross-section side view of a stage in the manufacturing process where a wet etch is performed using opening 274a to remove all of the N-type WFM 270b of FIG. 2E within the tub 261, including any N-type WFM 270b material between the nanoribbons 230. In embodiments, the wet etch process may be used to avoid damage to the nanoribbons 230. In embodiments, the wet etch process goes all the way to the bottom layer 220. In legacy implementations, a dry etch process would likely damage one or more of the stack of nanoribbons 230.

FIG. 2G shows a cross-section side view of a stage in the manufacturing process where the mask 274 of FIG. 2E is removed. In embodiments, this process may be referred to as an ash process. Note that the stack of nanoribbons 230 may have a width W and have an end cap width E as the width between the stack of nanoribbons and the wall 216 or the wall 214. Because a wet etch process was used above with respect to FIG. 2F, a wider width W may be used as compared to legacy processes, because the wet etch process may be adjusted/increased to remove all of the N-type WFM 270b of FIG. 2F that may be between each of the individual nanoribbons 230 without any parasitic N-P boundary excessive wet etch bias. In tub architecture N-P boundary is fixed by the tub wall 214 and therefore allows aggressive wet etches to be employed inside tub 261 without any movement of the N-P boundary. In addition, the wet etch enables much lower values for E between the stack of nanoribbons 230 and the walls 214, 216 than conventional legacy dry etch processes which in turn enables higher transistor densities.

FIG. 2H shows a cross-section side view of a stage in the manufacturing process where a P-type WFM 244, which may be similar to gate metal 144 of FIG. 1, is placed around the nanoribbons 230 and above the bottom layer 220. In embodiments, the P-type WFM 244 may also be placed above the N-type WFM 270a, and also above the walls 212, 214, 216. In embodiments, a P-type WFM layer 244a may be on top of the N-type WFM 270a. In embodiments, a thickness of the P-type WFM layer 244a may be on the order of 10 to 15 nm. In some embodiments there may be no P-type WFM layer 244a. In embodiments, this may be referred to as PMOS saturation.

FIG. 2I shows a cross-section side view of a stage in the manufacturing process where a planarization occurs to produce the surface 276, where a top of the walls 212, 214, 216 and a top of the P-type WFM layer 244a and a top of the P-type WFM layer 244b are in a plane. In embodiments, the planarization may be performed using CMP.

FIG. 2J shows a cross-section side view of a stage in the manufacturing process where recess 277a is formed above the P-type WFM layer 244a between walls 212, 214, and recess 277b is formed above the P-type WFM layer 244b between walls 214, 216.

In embodiments, multi-Vt may be achieved by volume less dipoles pattern and annealed before WFM fill patterning. Multiple WFM materials may be used.

In embodiments, the NMOS 270a and the PMOS 244b may have just one WFM of the same polarity as their respective gates, such that the gate operates with WFM in saturation mode, making Vt uniform at the end caps, such as shown in FIG. 2G, even when the end caps are narrow.

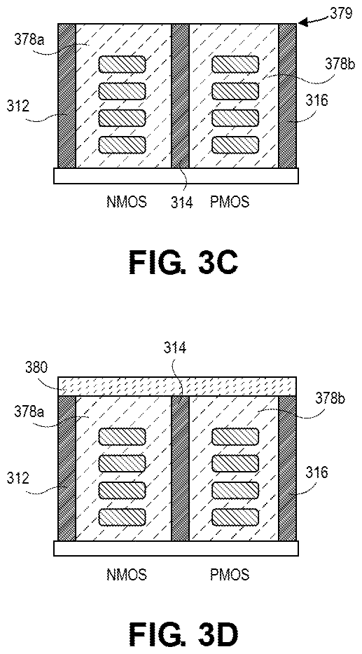

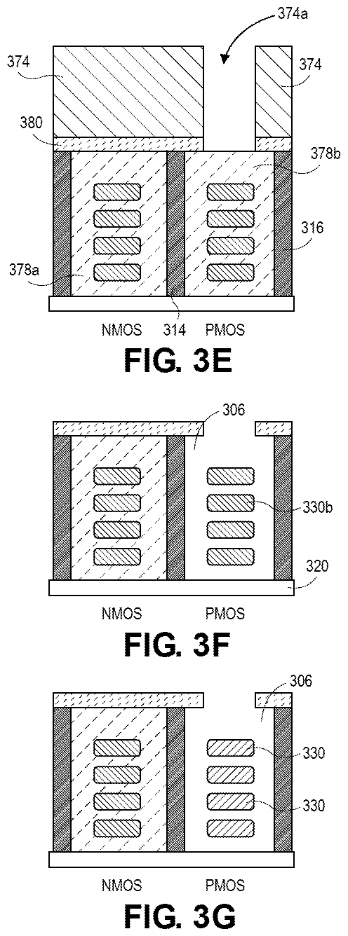

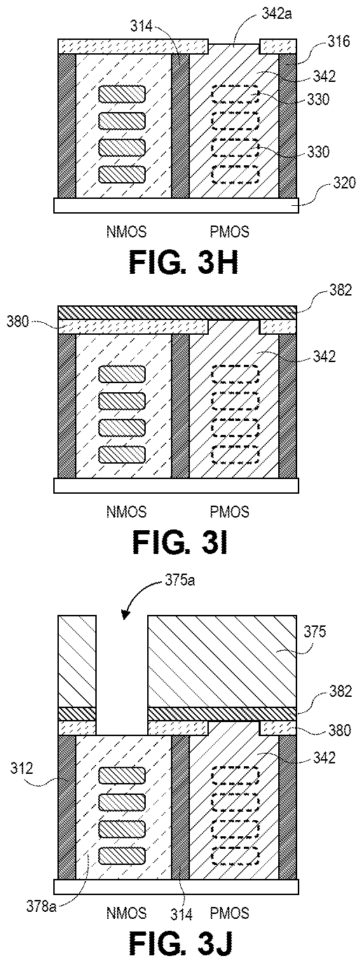

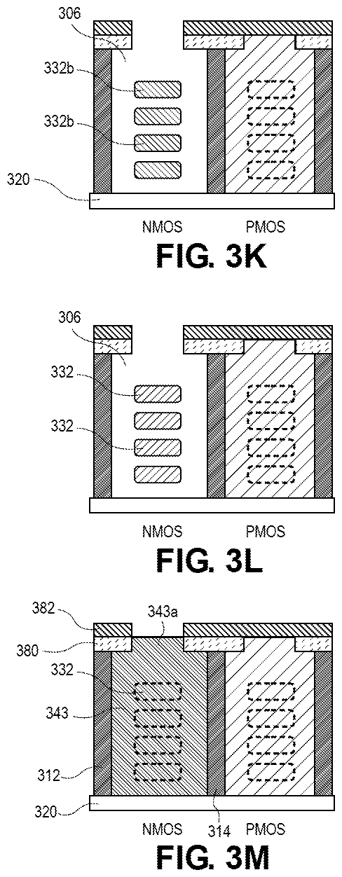

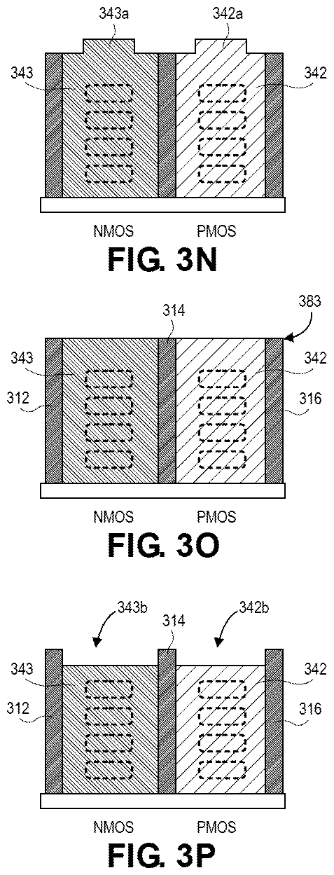

FIGS. 3A-3P illustrate cross-section side views of stages in a manufacturing process for creating a self-aligned epitaxial structure source/drain within a tub gate architecture, in accordance with various embodiments.

Low resistance TCN on epitaxial structure layers may be very dependent upon having a larger epitaxial structure volume and a high active doping concentration at the silicide/epitaxial structure interface. In embodiments, larger epitaxial structure volumes allow more proportion of the epitaxial structure bulk, which may include a high active dopant, and a high germanium percentage within silicon germanium (SiGe) with respect to a total epitaxial structure volume, and may ensure a high active dopant, high germanium percentage at the silicide/EPI interface. As a result, this may lead to lower resistivity and higher performance. However, in legacy implementations, epitaxial structure growth without any epitaxial structure wingspan barriers may risk shorts between N-N, P-P, and N-P, where multiple epitaxial structures may merge between different devices.

Turning back to embodiments, FIG. 3A shows a cross-section side view, which may be similar to cross-section side view B-B′ of integrated circuit structure 100A and diagram 100C of FIG. 1, of a stage in the manufacturing process that includes a bottom layer 320, and walls 312, 314, 316 that form tub 363 in NMOS region 324 and form tub 360 in PMOS region 326, which may be similar to bottom layer 120, walls 112, 114, 116, tubs 163, 160, NMOS region 124, and PMOS region 126 of FIG. 1.

In embodiments, tub 363 includes a stack of nanoribbons 332b, which may be similar to stack of nanoribbons 132b of FIG. 1. Tub 360 includes a stack of nanoribbons 330b, which may be similar to stack of nanoribbons 132b, 130 of FIG. 1. Note: tub 160 of FIG. 1 does not show any nanoribbons. Note that the stack of nanoribbons 332b, 330b are not surrounded by any epitaxial structure. In embodiments, the tubs 363, 360 may be in a source region, such as source region 150 of FIG. 1, or may be in a drain region, such as drain region 154 of FIG. 1.

FIG. 3B shows a cross-section side view of a stage in the manufacturing process where a sacrificial material 378 is placed above the bottom layer 320, between the stack of nanoribbons 332b, between the stack of nanoribbons 330b, and above the walls 312, 314, 316. In embodiments, the sacrificial material 378 may include tungsten (W) that may be deposited using a chemical vapor deposition process. A first portion of sacrificial material 378a may be between walls 312, 314, and a second portion of sacrificial material 378b may be between walls 314, 316.

FIG. 3C shows a cross-section side view of a stage in the manufacturing process where a planarization occurs to produce surface 379. In embodiments, the planarization may be performed using a CMP. In embodiments, a top of the walls 312, 314, 316, a top of the first portion of sacrificial material 378a, and a top of the second portion of sacrificial material 378b may form a plane at the surface 379.

FIG. 3D shows a cross-section side view of a stage in the manufacturing process where a first hard mask 380 is placed on a top of the walls 312, 314, 316, above the first portion of sacrificial material 378a, and above the second portion of sacrificial material 378b. In embodiments, the first hard mask 380 may include SiN, SiC, SiO, or SiCN.

FIG. 3E shows a cross-section side view of a stage in the manufacturing process where a mask 374 is placed above the first hard mask 380. In embodiments, the mask 374 may be a carbon hard mask. After the mask 374 is placed, an opening 374a is made through the mask 374 and through the first hard mask 380 to expose a top of the second portion of sacrificial material 378b. Note that, similar to FIG. 2E, the opening 374a may be placed sufficiently away from the walls 314, 316, such that any edge placement error that may result from the normal manufacturing process would not cause the opening 374a to expose any portion of the first portion of sacrificial material 378a.

FIG. 3F shows a cross-section side view of a stage in the manufacturing process where a wet etch is performed to remove all of the second portion of sacrificial material 378b of FIG. 3E around the stack of nanoribbons 330b, and above the bottom layer 320. This exposes a surface of the spacer 306, which may be similar to spacer 106 that is adjacent to tub 160 of FIG. 1. In addition, an ash process may be used to remove the mask 374 of FIG. 3E from the top of the first hard mask 380.

FIG. 3G shows a cross-section side view of a stage in the manufacturing process where a PMOS undercut is performed to remove the nanoribbons 330b of FIG. 3A to reveal edges of nanoribbons 330 that are within the spacer 306. In some embodiments, the nanoribbons 330 may be slightly recessed into the spacer 306.

FIG. 3H shows a cross-section side view of a stage in the manufacturing process where a P-type epitaxial structure 342 is grown on and around the edges of nanoribbons 330, above the bottom layer 320 and between the walls 314, 316. In embodiments, a portion 342a of the P-type epitaxial structure 342 may extend into the opening 374a of FIG. 3E within the first hard mask 380. This may be done to ensure that the entire volume of tub 360 of FIG. 3A is filled with P-type epitaxial structure 342.

FIG. 3I shows a cross-section side view of a stage in the manufacturing process where a second hard mask 382 is deposited on the first hard mask 380, and also covers and protects the P-type epitaxial structure 342.

FIG. 3J shows a cross-section side view of a stage in the manufacturing process where a second mask 375, which may be similar to mask 374 of FIG. 3E, is placed on the second hard mask 382. After the second mask 375 is placed, an opening 375a is made through the second mask 375, through the second hard mask 382 and through the first hard mask 380 to expose a top of the first portion of sacrificial material 378a. Note that, similar to FIG. 3E, the opening 375a may be placed sufficiently away from the walls 312, 314, such that any edge placement error that may result from the normal manufacturing process would not cause the opening 375a to expose any portion of the P-type epitaxial structure 342.

FIG. 3K shows a cross-section side view of a stage in the manufacturing process where a wet etch is performed to remove all of the first portion of sacrificial material 378a of FIG. 3J around the stack of nanoribbons 332b, and above the bottom layer 320. This exposes a surface of the spacer 306, which may be similar to spacer 106 that is adjacent to tub 163 of FIG. 1. In addition, an ash process may be used to remove the second mask 375 of FIG. 3E from on top of the first hard mask 380.

FIG. 3L shows a cross-section side view of a stage in the manufacturing process where an NMOS undercut is performed to remove the nanoribbons 332b of FIG. 3A to reveal edges of nanoribbons 332 that are within the spacer 306. In some embodiments, the nanoribbons 332 may be slightly recessed into the spacer 306.

FIG. 3M shows a cross-section side view of a stage in the manufacturing process where an N-type epitaxial structure 343 is grown on and around the edges of nanoribbons 332, above the bottom layer 320 and between the walls 312, 314. In embodiments, a portion 343a of the N-type epitaxial structure 343 may extend into the opening 375a of FIG. 3J within the first hard mask 380 and second hard mask 382. This may be done to ensure that the entire volume of tub 363 of FIG. 3A is filled with N-type epitaxial structure 343.

FIG. 3N shows a cross-section side view of a stage in the manufacturing process where the first hard mask 380 and the second hard mask 382 are removed, exposing a portion 343a of the N-type epitaxial structure 343 and exposing a portion 342a of the P-type epitaxial structure 342.

FIG. 3O shows a cross-section side view of a stage in the manufacturing process where a planarization happens to remove the portion 343a of the N-type epitaxial structure 343 and exposing a portion 342a of the P-type epitaxial structure 342 of FIG. 3N, leaving a planar surface 383 on the top of the walls 312, 314, 316, a top of the N-type epitaxial structure 343, and a top of the P-type epitaxial structure 342. In embodiments, the planarization may occur using CMP.

FIG. 3P shows a cross-section side view of a stage in the manufacturing process where an etch occurs within the N-type epitaxial structure 343 to create recess 343b, and an etch occurs within the P-type epitaxial structure 342 to create recess 342b. In embodiments, the recesses 343b, 342b may be used to apply TCN onto the N-type epitaxial structure 343 or onto the P-type epitaxial structure 342, as described further below. In embodiments, the top surfaces of the N-type epitaxial structure 343 and the P-type epitaxial structure 342 are planar or are substantially planar.

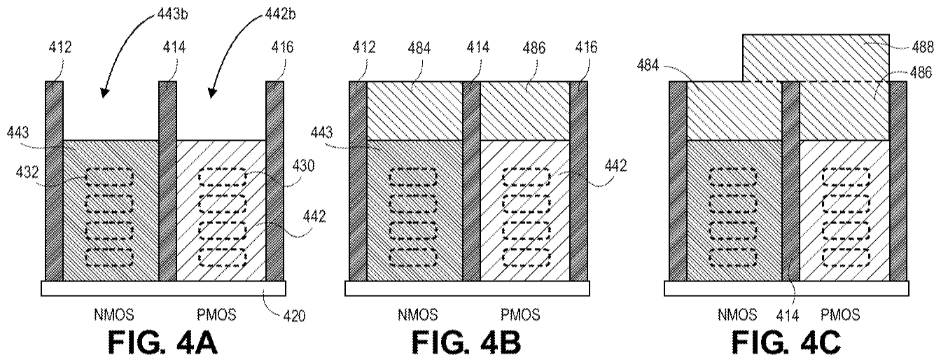

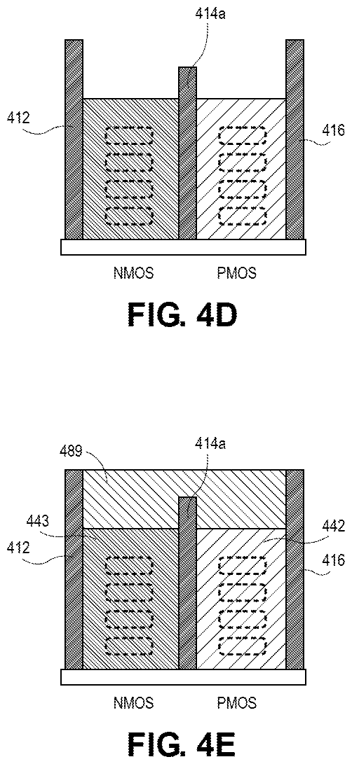

FIGS. 4A-4E illustrate cross-section side views of stages in a manufacturing process for creating a TCN on a self-aligned epitaxial structure source/drain within a tub gate architecture, in accordance with various embodiments. FIG. 4A shows cross-section side view, which may be similar to cross-section side view B-B′ of integrated circuit structure 100A and diagram 100C of FIG. 1, and which may also may be similar to FIG. 3P, of a stage in the manufacturing process that includes a bottom layer 420, and walls 412, 414, 416, with an N-type epitaxial structure 443 between walls 412, 414 and above bottom layer 420, and with P-type epitaxial structure 442 between walls 414, 416 and above bottom layer 420.

In embodiments, the N-type epitaxial structure 443 may be grown onto an edge of nanoribbons 432, which may be similar to nanoribbons 332 of FIG. 3L. In embodiments, the P-type epitaxial structure 442 may be grown onto an edge of nanoribbons 430, which may be similar nanoribbons 330 of FIG. 3G. In embodiments, a top surface of the P-type epitaxial structure 442 and a top surface of the N-type epitaxial structure 443 may be planar or substantially planar.

In embodiments, there may be a recess 443b into N-type epitaxial structure 443 below the top of walls 412, 414, and there may be a recess 442b into P-type epitaxial structure 442 below the top of walls 414, 416.

FIG. 4B shows a stage in the manufacturing process where a first TCN 484 may be formed on top of the N-type epitaxial structure 443 and may be self-aligned between walls 412, 414. A second TCN 486 may be formed on top of the P-type epitaxial structure 442 and may be self-aligned between walls 414, 416. In embodiments, the first TCN 484 and the second TCN 486 may include a metal, which may include titanium (Ti), TiN, W, or Cobolt.

FIG. 4C shows a stage in the manufacturing process where a connector 488 may be placed above the first TCN 484 and the second TCN 486 in order to electrically couple the first TCN 484 and the second TCN 486. In embodiments, connector 488, may be formed on top of the wall 414 using patterning processes known in the art.

FIG. 4D shows a stage in the manufacturing process, which may be subsequent to the stage shown in FIG. 4A, where the wall 414 of FIG. 4A has been recessed below a top of the walls 412, 416 to form wall 414a.

FIG. 4E shows a stage in the manufacturing process where a TCN 489 is placed between the walls 412, 416, above the N-type epitaxial structure 443, above the P-type epitaxial structure 442, and on top of the wall 414. In embodiments, the TCN 489 may be placed using a self-aligned process. In embodiments, the TCN 489 will electrically couple the N-type epitaxial structure 443 and the P-type epitaxial structure 442.

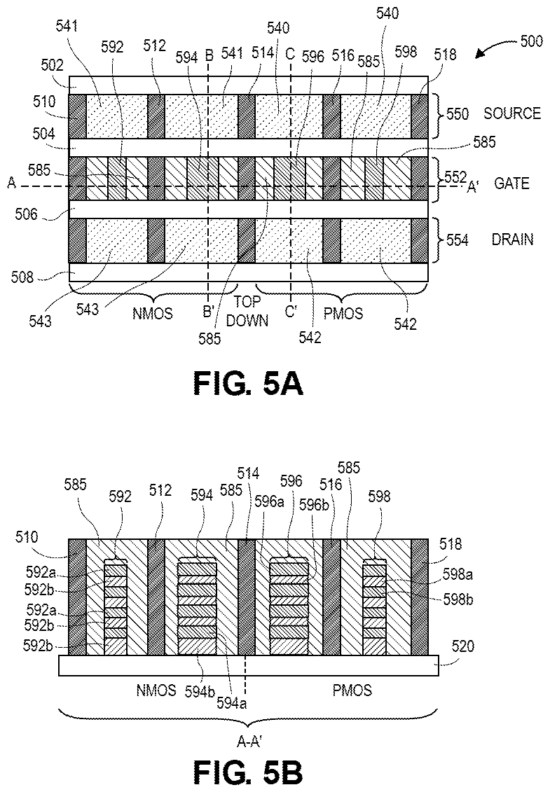

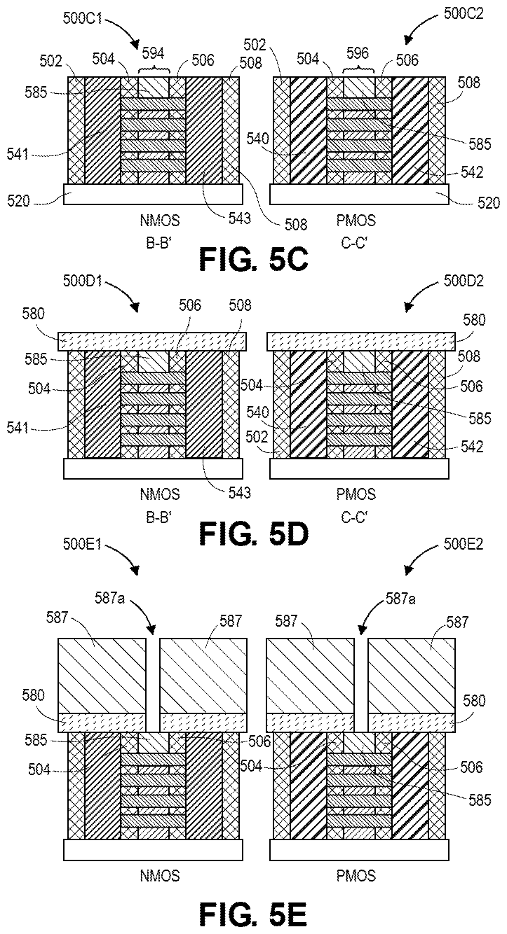

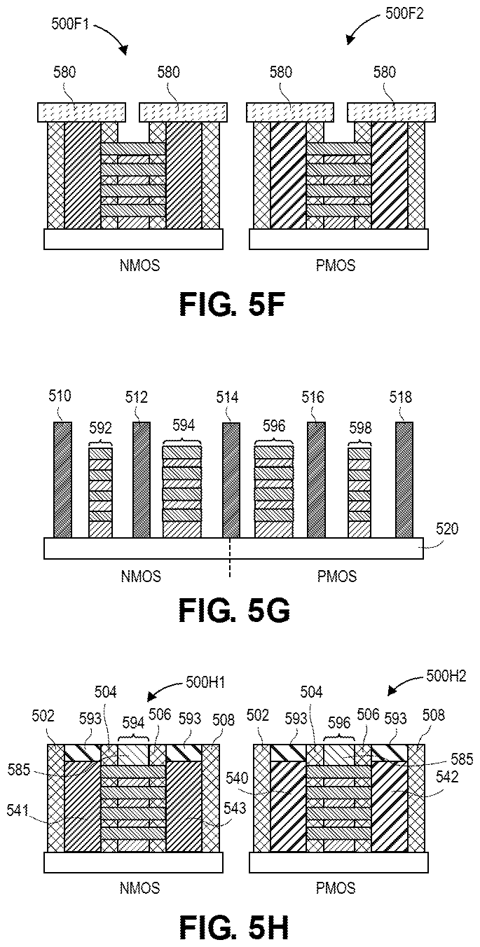

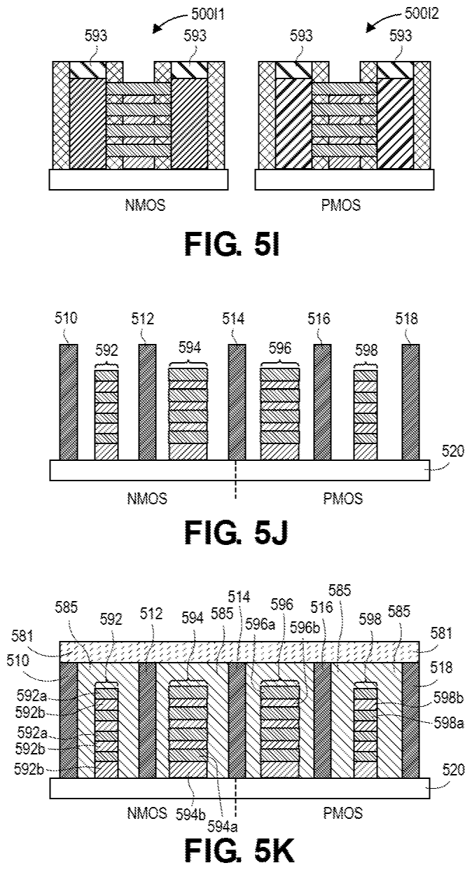

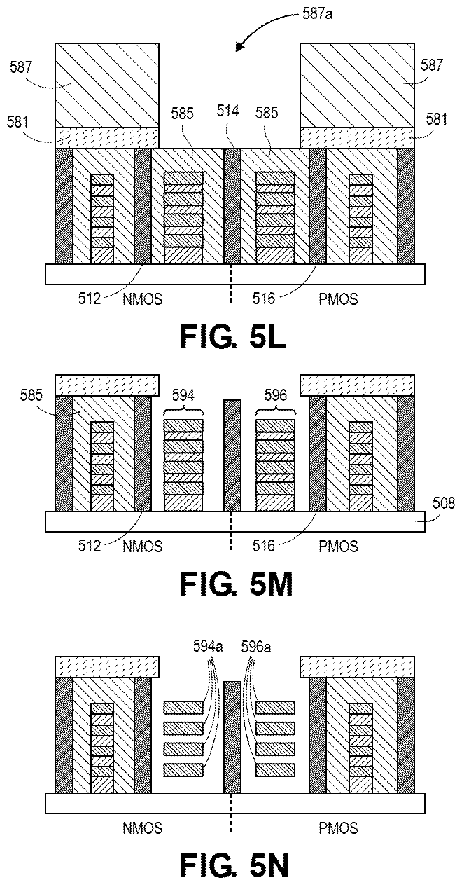

FIGS. 5A-5N illustrate a top-down view and various cross-section side views of stages in a manufacturing process for performing a poly silicon removal using an isotropic etch within a tub gate architecture. In legacy implementations, the poly silicon removal process, which may be referred to as PYREM, used dry etch processes that leaves poly silicon material residues, for example silicon, at the bottom of the gate or at gate end caps due to the dry etch process being aspect ratio dependent.

In embodiments described herein, using the tub architecture, an isotropic etch rather than a dry etch may be used to remove poly silicon material. As a result, the isotropic etch is able to completely eliminate poly silicon material residues within the gate, for example for gates with a critical dimension of less than 8 nm, or a gate end cap of less than 8 nm.

FIG. 5A shows a top-down view of integrated circuit structure 500 within a tub gate architecture, in a stage of the manufacturing process. In embodiments, a plurality of walls 510, 512, 514, 516, 518 intersect with a plurality of spacers 502, 504, 506, 508 to create a total of 12 tubs, which may be similar to tubs 163, 164, 165 of FIG. 1.

In embodiments, four tubs may include stacks of nanoribbons 592, 594, 596, 598 in a gate region 552, which may be similar to gate region 152 of FIG. 1. Four tubs may be within a source region 550, which may be similar to source region 150 of FIG. 1, and include a P-type epitaxial structure 540 and an N-type epitaxial structure 541. Four tubs may be within the drain region 554, which may be similar to drain regions 154 of FIG. 1, and may include P-type epitaxial structure 542 and an N-type epitaxial structure 543. In embodiments, the stacks of nanoribbons 592, 594, 596, 598 may be surrounded by a poly silicon material 585 within each tub.

FIG. 5B shows a cross-section side view through A-A′ of FIG. 5A of a stage in the manufacturing process, that shows walls 510, 512, 514, 516, 518 on a bottom layer 520, which may be similar to bottom layer 120 of FIG. 1. Stacks of nanoribbons 592, 594, 596, 598 are between, respectively, each of the walls 510, 512, 514, 516, 518 and are on the bottom layer 520. Poly silicon material 585 surrounds each of the stacks of nanoribbons 592, 594, 596, 598. In embodiments, the stack of nanoribbons 592 includes layers of silicon 592a interleaved with layers of silicon germanium 592b, the stack of nanoribbons 594 includes layers of silicon 594a interleaved with layers of silicon germanium 594b, the stack of nanoribbons 596 includes layers of silicon 596a interleaved with layers of silicon germanium 596b, and the stack of nanoribbons 598 includes layers of silicon 598a interleaved with layers of silicon germanium 598b.

FIG. 5C shows diagram 500C1 which is a cross-section side view through B-B′ of FIG. 5A and diagram 500C2 which is a cross-section side view through C-C′ of FIG. 5A, of a stage in the manufacturing process. Diagram 500C1 shows source epitaxial structure 541 between spacers 502, 504, stack of nanoribbons 594 between spacers 504, 506, with a poly silicon material 585 on top of the stack of nanoribbons 594, and a drain epitaxial structure 543 between spacers 506, 508.

Diagram 500C2 shows source epitaxial structure 540 between spacers 502, 504, stack of nanoribbons 596 between spacers 504, 506, with a poly silicon material 585 on top of the stack of nanoribbons 596, and a drain epitaxial structure 542 between spacers 506, 508.

FIG. 5D shows diagram 500D1, which may be similar to diagram 500C1 of FIG. 5C, of a stage in the manufacturing process where a hard mask 580 is deposited on top of the spacers 502, 504, 506, 508, on top of the source epitaxial structure 541 and the drain epitaxial structure 543, and on top of the poly silicon material 585. Similarly, in diagram 500D2, which may be similar to diagram 500C2 of FIG. 5C, the hard mask 580 may be deposited on the spacers 502, 504, 506, 508, on top of the source epitaxial structure 540 and the drain epitaxial structure 542, and on top of the poly silicon material 585.

FIG. 5E shows diagram 500E1, which may be similar to diagram 500D1 of FIG. 5D, and diagram 500E2, which may be similar to diagram 500D2 of FIG. 5D, of a stage in the manufacturing process where a mask 587 is placed on top of the hard mask 580. In embodiments, the mask 587 may be a carbon hard mask. In embodiments, an opening 587a may be formed into the mask 587 and through the hard mask 580 exposing the poly silicon material 585.

In embodiments, the opening 587a may be placed sufficiently away from the spacers 504, 506 such that the opening 587a will open only onto the poly silicon material 585. In embodiments, the opening 587a may be a distance of an edge placement error or greater away from the spacers 504, 506, as discussed above with respect to FIG. 2E.

FIG. 5F shows diagrams 500F1, which may be similar to diagram 500E1 of FIG. 5E, and diagram 500F2, which may be similar to diagram 500E2 of FIG. 5E, of a stage in the manufacturing process where an etch process, which may be a wet etch and/or an isotropic etch, has been performed to remove the poly silicon material 585 shown in FIG. 5E. Subsequently, in embodiments, an ash process has been performed to remove the mask 587 in FIG. 5E on top of the hard mask 580.

FIG. 5G shows a cross-section side view along A-A′ of FIG. 5A, where the poly silicon material 585 of FIG. 5B between the walls 510, 512, 514, 516, 518 has been removed to the bottom layer 520, as described in FIG. 5F, exposing the stacks of nanoribbons 592, 594, 596, 598.

FIG. 5H, which may be similar to FIG. 5C, shows diagram 500H1 which is a cross-section side view through B-B′ of FIG. 5A and diagram 500H2 which is a cross-section side view through C-C′ of FIG. 5A of a stage in the manufacturing process that uses a recessed epitaxial structure. Diagram 500H1 shows source epitaxial structure 541 between spacers 502, 504, stack of nanoribbons 594 between spacers 504, 506, with a poly silicon material 585 on top of the stack of nanoribbons 594, and a drain epitaxial structure 543 between spacers 506, 508. In embodiments, an epitaxial structure cap 593 is on top of the source epitaxial structure 541 and the drain epitaxial structure 543.

Diagram 500H2 shows source epitaxial structure 540 between spacers 502, 504, stack of nanoribbons 596 between spacers 504, 506, with a poly silicon material 585 on top of the stack of nanoribbons 596, and a drain epitaxial structure 542 between spacers 506, 508. In embodiments, the epitaxial structure cap 593 is on top of the source epitaxial structure 540 and the drain epitaxial structure 542.

FIG. 5I, which may be similar to FIG. 5H, shows diagram 500I1 and diagram 500I2, where an etching process has been applied to remove the poly silicon material 585 of FIG. 5H. In embodiments, the etching process may be an isotropic etch, and may include a wet etch. In embodiments, the epitaxial structure cap 593 protects the source epitaxial structure 541, drain epitaxial structure 543, source epitaxial structure 540, and drain epitaxial structure 542 during the etching process.

FIG. 5J shows a cross-section side view along A-A′ of FIG. 5A, where the poly silicon material 585 of FIG. 5B between the walls 510, 512, 514, 516, 518 has been removed, as described in FIG. 5I, to the bottom layer 520, exposing the stacks of nanoribbons 592, 594, 596, 598.

FIG. 5K shows a cross-section side view through A-A′ of FIG. 5A, that shows walls 510, 512, 514, 516, 518 on a bottom layer 520, which may be similar to bottom layer 120 of FIG. 1 of a stage in the manufacturing process that involves a patterned etch. Stacks of nanoribbons 592, 594, 596, 598 are between, respectively, each of the walls 510, 512, 514, 516, 518 and are on the bottom layer 520. Poly silicon material 585 surrounds each of the stacks of nanoribbons 592, 594, 596, 598.

In embodiments, the stack of nanoribbons 592 includes layers of silicon 592a interleaved with layers of silicon germanium 592b, the stack of nanoribbons 594 includes layers of silicon 594a interleaved with layers of silicon germanium 594b, the stack of nanoribbons 596 includes layers of silicon 596a interleaved with layers of silicon germanium 596b, and the stack of nanoribbons 598 includes layers of silicon 598a interleaved with layers of silicon germanium 598b.

In embodiments, a hard mask 581 may be placed on top of the walls 510, 512, 514, 516, 518 and on top of the poly silicon material 585.

FIG. 5L, which may be similar FIG. 5K, shows a stage in the manufacturing process where a mask 587 is placed above the hard mask 581. An opening 587a is made through the mask 587 and through the hard mask 581 exposing wall 514 and the poly silicon material 585 between walls 512, 516. Note that the opening 587a may be constructed in light of any edge placement error known with respect to the manufacturing process, so that only the poly silicon material 585 between the walls 512, 516 is exposed.

FIG. 5M, which may be similar to FIG. 5L, shows a stage in the manufacturing process where an isotropic etch has been performed to remove the poly silicon material 585 of FIG. 5L between the walls 512, 516 down to the bottom layer 520. Note that the poly silicon material 585 no longer surrounds the stacks of nanoribbons 594, 596. Subsequently, an ash process may be performed to remove the mask 587 as shown in FIG. 5L.

FIG. 5N, which may be similar to FIG. 5M, shows an etch of the silicon germanium 594b, 596b of FIG. 5B, leaving layers of silicon 594a, 596a. This may be referred to as a nanoribbon release process. By patterning the nanoribbon release using tub architecture the SiGe removal chemistry may be specifically tailored to each width of the nanoribbon devices preventing thus excessive etch or potential etch damage incurred upon the narrow stacks of layers of silicon 594a, 596a.

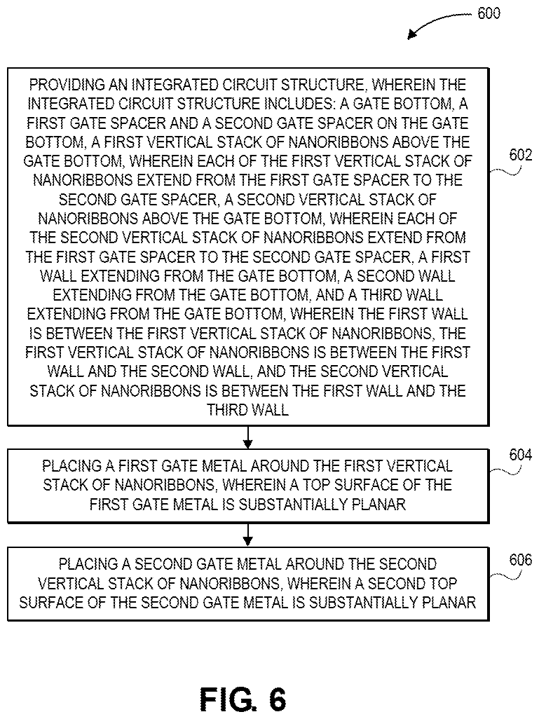

FIG. 6 illustrates an example process for manufacturing of integrated circuit structures within a tub gate architecture that include aligned self-aligned metal gates, in accordance with various embodiments. Process 600 may be performed using the systems, apparatus, processes, and/or techniques as described herein, and in particular with respect to FIGS. 1-5N.

At block 602, the process may include providing an integrated circuit structure, wherein the integrated circuit structure includes: a gate bottom, a first gate spacer and a second gate spacer on the gate bottom, a first vertical stack of nanoribbons above the gate bottom, wherein each of the first vertical stack of nanoribbons extend from the first gate spacer to the second gate spacer, a second vertical stack of nanoribbons above the gate bottom, wherein each of the second vertical stack of nanoribbons extend from the first gate spacer to the second gate spacer, a first wall extending from the gate bottom, a second wall extending from the gate bottom, and a third wall extending from the gate bottom, wherein the first wall is between the first vertical stack of nanoribbons, the first vertical stack of nanoribbons is between the first wall and the second wall, and the second vertical stack of nanoribbons is between the first wall and the third wall.

At block 604, the process may further include placing a first gate metal around the first vertical stack of nanoribbons, wherein a top surface of the first gate metal is substantially planar.

At block 606, the process may further include placing a second gate metal around the second vertical stack of nanoribbons, wherein a second top surface of the second gate metal is substantially planar.

Implementations of embodiments of the invention may be formed or carried out on a substrate, such as a semiconductor substrate. In one implementation, the semiconductor substrate may be a crystalline substrate formed using a bulk silicon or a silicon-on-insulator substructure. In other implementations, the semiconductor substrate may be formed using alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of group III-V or group IV materials. Although a few examples of materials from which the substrate may be formed are described here, any material that may serve as a foundation upon which a semiconductor device may be built falls within the spirit and scope of the present invention.

A plurality of transistors, such as metal-oxide-semiconductor field-effect transistors (MOSFET or simply MOS transistors), may be fabricated on the substrate. In various implementations of the invention, the MOS transistors may be planar transistors, nonplanar transistors, or a combination of both. Nonplanar transistors include FinFET transistors such as double-gate transistors and tri-gate transistors, and wrap-around or all-around gate transistors such as nanoribbon and nanowire transistors. Although the implementations described herein may illustrate only planar transistors, it should be noted that the invention may also be carried out using nonplanar transistors.

Each MOS transistor includes a gate stack formed of at least two layers, a gate dielectric layer and a gate electrode layer. The gate dielectric layer may include one layer or a stack of layers. The one or more layers may include silicon oxide, silicon dioxide (SiO₂) and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric layer include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric layer to improve its quality when a high-k material is used.

The gate electrode layer is formed on the gate dielectric layer and may consist of at least one P-type workfunction metal or N-type workfunction metal, depending on whether the transistor is to be a PMOS or an NMOS transistor. In some implementations, the gate electrode layer may consist of a stack of two or more metal layers, where one or more metal layers are workfunction metal layers and at least one metal layer is a fill metal layer.

For a PMOS transistor, metals that may be used for the gate electrode include, but are not limited to, ruthenium, palladium, platinum, cobalt, nickel, and conductive metal oxides, e.g., ruthenium oxide. A P-type metal layer will enable the formation of a PMOS gate electrode with a workfunction that is between about 4.9 eV and about 5.2 eV. For an NMOS transistor, metals that may be used for the gate electrode include, but are not limited to, hafnium, zirconium, titanium, tantalum, aluminum, alloys of these metals, and carbides of these metals such as hafnium carbide, zirconium carbide, titanium carbide, tantalum carbide, and aluminum carbide. An N-type metal layer will enable the formation of an NMOS gate electrode with a workfunction that is between about 3.9 eV and about 4.2 eV.

In some implementations, the gate electrode may consist of a “U”-shaped structure that includes a bottom portion substantially parallel to the surface of the substrate and two sidewall portions that are substantially perpendicular to the top surface of the substrate. In another implementation, at least one of the metal layers that form the gate electrode may simply be a planar layer that is substantially parallel to the top surface of the substrate and does not include sidewall portions substantially perpendicular to the top surface of the substrate. In further implementations of the invention, the gate electrode may consist of a combination of U-shaped structures and planar, non-U-shaped structures. For example, the gate electrode may consist of one or more U-shaped metal layers formed atop one or more planar, non-U-shaped layers.

In some implementations of the invention, a pair of sidewall spacers may be formed on opposing sides of the gate stack that bracket the gate stack. The sidewall spacers may be formed from a material such as silicon nitride, silicon oxide, silicon carbide, silicon nitride doped with carbon, and silicon oxynitride. Processes for forming sidewall spacers are well known in the art and generally include deposition and etching process steps. In an alternate implementation, a plurality of spacer pairs may be used, for instance, two pairs, three pairs, or four pairs of sidewall spacers may be formed on opposing sides of the gate stack.

As is well known in the art, source and drain regions are formed within the substrate adjacent to the gate stack of each MOS transistor. The source and drain regions are generally formed using either an implantation/diffusion process or an etching/deposition process. In the former process, dopants such as boron, aluminum, antimony, phosphorous, or arsenic may be ion-implanted into the substrate to form the source and drain regions. An annealing process that activates the dopants and causes them to diffuse further into the substrate typically follows the ion implantation process. In the latter process, the substrate may first be etched to form recesses at the locations of the source and drain regions. An epitaxial structure deposition process may then be carried out to fill the recesses with material that is used to fabricate the source and drain regions. In some implementations, the source and drain regions may be fabricated using a silicon alloy such as silicon germanium or silicon carbide. In some implementations the epitaxial structurely deposited silicon alloy may be doped in situ with dopants such as boron, arsenic, or phosphorous. In further embodiments, the source and drain regions may be formed using one or more alternate semiconductor materials such as germanium or a group III-V material or alloy. And in further embodiments, one or more layers of metal and/or metal alloys may be used to form the source and drain regions.

One or more interlayer dielectrics (ILD) are deposited over the MOS transistors. The ILD layers may be formed using dielectric materials known for their applicability in integrated circuit structures, such as low-k dielectric materials. Examples of dielectric materials that may be used include, but are not limited to, silicon dioxide (SiO₂), carbon doped oxide (CDO), silicon nitride, organic polymers such as perfluorocyclobutane or polytetrafluoroethylene, fluorosilicate glass (FSG), and organosilicates such as silsesquioxane, siloxane, or organosilicate glass. The ILD layers may include pores or air gaps to further reduce their dielectric constant.

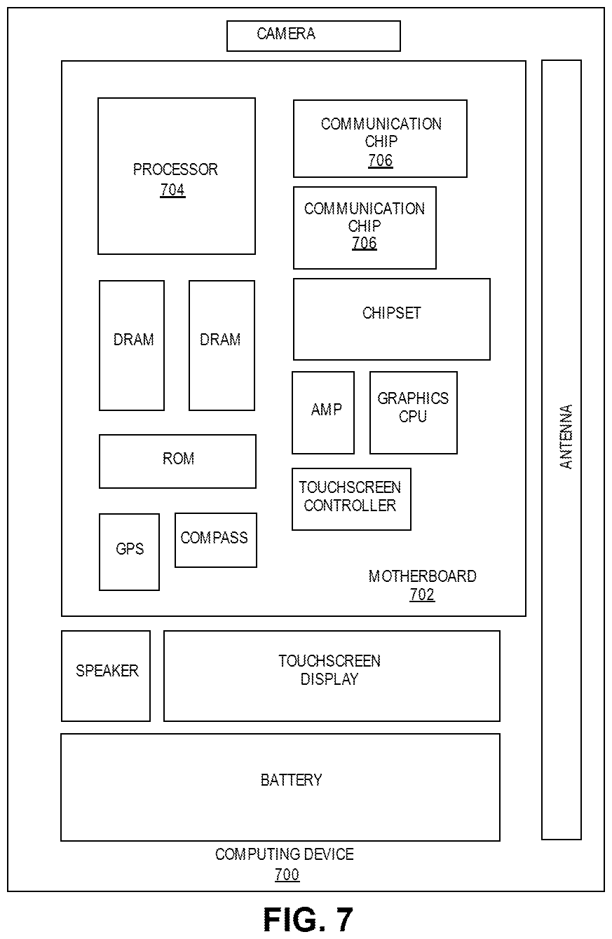

FIG. 7 illustrates a computing device 700 in accordance with one implementation of the invention. The computing device 700 houses a board 702. The board 702 may include a number of components, including but not limited to a processor 704 and at least one communication chip 706. The processor 704 is physically and electrically coupled to the board 702. In some implementations the at least one communication chip 706 is also physically and electrically coupled to the board 702. In further implementations, the communication chip 706 is part of the processor 704.

Depending on its applications, computing device 700 may include other components that may or may not be physically and electrically coupled to the board 702. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 706 enables wireless communications for the transfer of data to and from the computing device 700. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 706 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 700 may include a plurality of communication chips 706. For instance, a first communication chip 706 may be dedicated to shorter range wireless communications such as Wi-Fi and Bluetooth and a second communication chip 706 may be dedicated to longer range wireless communications such as GPS, EDGE, GPRS, CDMA, WiMAX, LTE, Ev-DO, and others.

The processor 704 of the computing device 700 includes an integrated circuit die packaged within the processor 704. In some implementations of the invention, the integrated circuit die of the processor includes one or more devices, such as MOS-FET transistors built in accordance with implementations of the invention. The term “processor” may refer to any device or portion of a device that processes electronic data from registers and/or memory to transform that electronic data into other electronic data that may be stored in registers and/or memory.

The communication chip 706 also includes an integrated circuit die packaged within the communication chip 706. In accordance with another implementation of the invention, the integrated circuit die of the communication chip includes one or more devices, such as MOS-FET transistors built in accordance with implementations of the invention.

In further implementations, another component housed within the computing device 700 may contain an integrated circuit die that includes one or more devices, such as MOS-FET transistors built in accordance with implementations of the invention.

In various implementations, the computing device 700 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 700 may be any other electronic device that processes data.

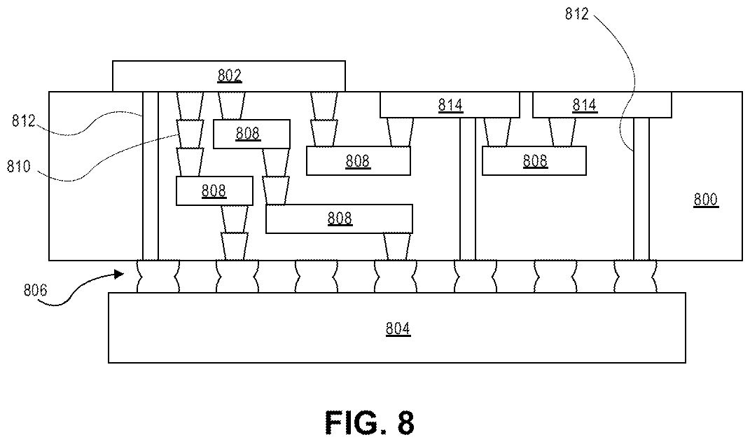

FIG. 8 illustrates an interposer 800 that includes one or more embodiments of the invention. The interposer 800 is an intervening substrate used to bridge a first substrate 802 to a second substrate 804. The first substrate 802 may be, for instance, an integrated circuit die. The second substrate 804 may be, for instance, a memory module, a computer motherboard, or another integrated circuit die. Generally, the purpose of an interposer 800 is to spread a connection to a wider pitch or to reroute a connection to a different connection. For example, an interposer 800 may couple an integrated circuit die to a ball grid array (BGA) 806 that can subsequently be coupled to the second substrate 804. In some embodiments, the first and second substrates 802/804 are attached to opposing sides of the interposer 800. In other embodiments, the first and second substrates 802/804 are attached to the same side of the interposer 800. And in further embodiments, three or more substrates are interconnected by way of the interposer 800.

The interposer 800 may be formed of an epoxy resin, a fiberglass-reinforced epoxy resin, a ceramic material, or a polymer material such as polyimide. In further implementations, the interposer may be formed of alternate rigid or flexible materials that may include the same materials described above for use in a semiconductor substrate, such as silicon, germanium, and other group III-V and group IV materials.

The interposer 800 may include metal interconnects 808 and vias 810, including but not limited to through-silicon vias (TSVs) 812. The interposer 800 may further include embedded devices 814, including both passive and active devices. Such devices include, but are not limited to, capacitors, decoupling capacitors, resistors, inductors, fuses, diodes, transformers, sensors, and electrostatic discharge (ESD) devices. More complex devices such as radio-frequency (RF) devices, power amplifiers, power management devices, antennas, arrays, sensors, and MEMS devices may also be formed on the interposer 800. In accordance with embodiments of the invention, apparatuses or processes disclosed herein may be used in the fabrication of interposer 800.

Although certain embodiments have been illustrated and described herein for purposes of description, a wide variety of alternate and/or equivalent embodiments or implementations calculated to achieve the same purposes may be substituted for the embodiments shown and described without departing from the scope of the present disclosure. This application is intended to cover any adaptations or variations of the embodiments discussed herein. Therefore, it is manifestly intended that embodiments described herein be limited only by the claims.

Where the disclosure recites “a” or “a first” element or the equivalent thereof, such disclosure includes one or more such elements, neither requiring nor excluding two or more such elements. Further, ordinal indicators (e.g., first, second or third) for identified elements are used to distinguish between the elements, and do not indicate or imply a required or limited number of such elements, nor do they indicate a particular position or order of such elements unless otherwise specifically stated.

Various embodiments may include any suitable combination of the above-described embodiments including alternative (or) embodiments of embodiments that are described in conjunctive form (and) above (e.g., the “and” may be “and/or”). Furthermore, some embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

The above description of illustrated embodiments, including what is described in the Abstract, is not intended to be exhaustive or to limit embodiments to the precise forms disclosed. While specific embodiments are described herein for illustrative purposes, various equivalent modifications are possible within the scope of the embodiments, as those skilled in the relevant art will recognize.

These modifications may be made to the embodiments in light of the above detailed description. The terms used in the following claims should not be construed to limit the embodiments to the specific implementations disclosed in the specification and the claims. Rather, the scope of the invention is to be determined entirely by the following claims, which are to be construed in accordance with established doctrines of claim interpretation.

The following paragraphs describe examples of various embodiments.

### Examples

Example 1 is an integrated circuit structure comprising: a first vertical stack of nanoribbons above a gate bottom that extends from a first gate spacer to a second gate spacer; a second vertical stack of nanoribbons above the gate bottom that extends from the first gate spacer to the second gate spacer; a first wall extending from the gate bottom between the first vertical stack of nanoribbons and the second vertical stack of nanoribbons; a second wall extending from the gate bottom and a third wall extending from the gate bottom, wherein the first vertical stack of nanoribbons is between the second wall and the first wall, and wherein the second vertical stack of nanoribbons is between the third wall and the first wall; and a first gate metal surrounding the first vertical stack of nanoribbons and a second gate metal surrounding the second stack of nanoribbons, wherein a first top surface of the first gate metal and a second top surface of the second gate metal are planar.

Example 2 includes the integrated circuit structure of example 1, wherein the first vertical stack of nanoribbons extend at least partially into the first gate spacer and into the second gate spacer.

Example 3 includes the integrated circuit structure of examples 1 or 2, wherein the second vertical stack of nanoribbons extend at least partially into the first gate spacer and into the second gate spacer.

Example 4 includes the integrated circuit structure of examples 1, 2, or 3, wherein the first wall, the second wall, and the third wall are substantially perpendicular to the first gate spacer or to the second gate spacer.

Example 5 includes the integrated circuit structure of examples 1, 2, 3, or 4, wherein the first gate metal includes an N-type workfunction metal and wherein the second gate metal includes a P-type workfunction metal.

Example 6 includes the integrated circuit structure of examples 1, 2, 3, 4, or 5, wherein the first top surface of the first gate metal and the second top surface of the second gate metal are substantially in a same plane.

Example 7 includes the integrated circuit structure of examples 1, 2, 3, 4, 5, or 6, wherein a top of the first wall, a top of the second wall, a top of the third wall, the first top surface of the first gate metal, and the second top surface of the second gate metal are substantially in a same plane.

Example 8 includes the integrated circuit structure of examples 1, 2, 3, 4, 5, 6, or 7, wherein a top of the first wall, a top of the second wall, and a top of the third wall are in a first plane, wherein the first top surface of the first gate metal and the second top surface of the second gate metal are in a second plane, and wherein the second plane is below the first plane with respect to the gate bottom.

Example 9 includes the integrated circuit structure of examples 1, 2, 3, 4, 5, 6, 7, or 8, wherein the first gate metal completely surrounds each of the first vertical stack of nanoribbons, and wherein the second gate metal completely surrounds each of the second vertical stack of nanoribbons.

Example 10 includes the integrated structure of examples 1, 2, 3, 4, 5, 6, 7, 8, or 9, wherein the first wall, the second wall, and the third wall include a selected one or more of: silicon, nitrogen, carbon, oxygen, hafnium, SinN, SiC, SiON, SiCN, HfO or HfN.

Example 11 includes the integrated structure of examples 1, 2, 3, 4, 5, 6, 7, 8, 9, or 10, wherein the first top surface of the first gate metal includes a layer of the second gate metal.

Example 12 includes integrated circuit structure of examples 1, 2, 3, 4, 5, 6, 7, 8, 9, 10, or 11, wherein a width of each of the first vertical stack of nanoribbons or a width of each of the second vertical stack of nanoribbons is greater than 25 nm.

Example 13 is an integrated circuit structure comprising: a bottom layer; a first epitaxial structure on the bottom layer and between a first gate spacer and a second gate spacer; a second epitaxial structure on the bottom that extends from the first gate spacer to the second gate spacer; a first wall extending from the bottom layer and between the first gate spacer and the second gate spacer, wherein the first wall separates the first epitaxial structure and the second epitaxial structure from each other; a second wall extending from the bottom layer and between the first gate spacer and the second gate spacer, wherein the first epitaxial structure is between the second wall and the first wall; a third wall extending from the bottom layer and between the first gate spacer and the second gate spacer, wherein the second epitaxial structure is between the third wall and the first wall; and wherein a first top surface of the first epitaxial structure and a second top surface of the second epitaxial structure are planar.

Example 14 includes the integrated circuit structure of example 13, wherein the first top surface of the first epitaxial structure and the second top surface of the second epitaxial structure are in a same plane.

Example 15 includes the integrated circuit structure of example 14, wherein a top of the second wall and a top of the third wall are in the same plane.

Example 16 includes the integrated circuit structure of example 15, wherein a top of the first wall is in the same plane.

Example 17 includes the integrated circuit structure of examples 13, 14, 15, or 16, further comprising: a first vertical stack of nanoribbons within the first gate spacer; a second vertical stack of nanoribbons within the second gate spacer; and wherein the first epitaxial structure is directly coupled with a portion of the first vertical stack of nanoribbons, and wherein the second epitaxial structure is directly coupled with a portion of the second vertical stack of nanoribbons.

Example 18 includes the integrated circuit structure of examples 13, 14, 15, 16, or 17, wherein the first epitaxial structure is a P-type epitaxial structure, and the second epitaxial structure is an N-type epitaxial structure.

Example 19 includes the integrated circuit structure of examples 13, 14, 15, 16, 17, or 18, further comprising a terminal contact above the first wall, wherein the terminal contact is between the second wall and the third wall, and wherein the terminal contact is electrically coupled with the first epitaxial structure and electrically coupled with the second epitaxial structure.

Example 20 includes the integrated circuit structure of examples 13, 14, 15, 16, 17, 18, or 19, further comprising a first terminal contact on the first epitaxial structure and a terminal contact on the second epitaxial structure, wherein the first terminal contact is between the second wall and the first wall, wherein the second terminal contact is between the third wall and the first wall, and wherein the first terminal contact and the second terminal contact are electrically isolated from each other.

Example 21 includes the integrated circuit structure of examples 13, 14, 15, 16, 17, 18, 19, or 20, wherein the first wall, the second wall, or the third wall extend above the first top surface of the first epitaxial structure or the second top surface of the second epitaxial structure.

Example 22 is a method comprising: providing an integrated circuit structure, wherein the integrated circuit structure includes: a gate bottom, a first gate spacer and a second gate spacer on the gate bottom, a first vertical stack of nanoribbons above the gate bottom, wherein each of the first vertical stack of nanoribbons extend from the first gate spacer to the second gate spacer, a second vertical stack of nanoribbons above the gate bottom, wherein each of the second vertical stack of nanoribbons extend from the first gate spacer to the second gate spacer, a first wall extending from the gate bottom, a second wall extending from the gate bottom, and a third wall extending from the gate bottom, wherein the first wall is between the first vertical stack of nanoribbons, the first vertical stack of nanoribbons is between the first wall and the second wall, and the second vertical stack of nanoribbons is between the first wall and the third wall; placing a first gate metal around the first vertical stack of nanoribbons, wherein a top surface of the first gate metal is substantially planar; and placing a second gate metal around the second vertical stack of nanoribbons, wherein a second top surface of the second gate metal is substantially planar.

Example 23 includes the method of example 22, wherein placing the second gate metal around the second vertical stack of nanoribbons further includes: placing the first gate metal around the second vertical stack of nanoribbons; removing the first gate metal around the second vertical stack of nanoribbons; and placing the second gate metal around the second vertical stack of nanoribbons.

Example 24 includes the method of example 23, wherein removing the first gate metal around the second vertical stack of nanoribbons further includes applying a wet etch to the first gate metal around the second vertical stack of nanoribbons.

Example 25 includes the method of examples 22, 23, or 24, wherein the first gate metal is a N-type gate metal, and wherein the second gate metal is a P-type gate metal.

What is claimed is:

1. An integrated circuit structure comprising:
a first vertical stack of nanoribbons above a gate bottom that extends from a first gate spacer to a second gate spacer;
a second vertical stack of nanoribbons above the gate bottom that extends from the first gate spacer to the second gate spacer;
a first wall extending from the gate bottom between the first vertical stack of nanoribbons and the second vertical stack of nanoribbons;
a second wall extending from the gate bottom and a third wall extending from the gate bottom, wherein the first vertical stack of nanoribbons is between the second wall and the first wall, and wherein the second vertical stack of nanoribbons is between the third wall and the first wall; and
a first gate metal surrounding the first vertical stack of nanoribbons and a second gate metal surrounding the second stack of nanoribbons, wherein a first top surface of the first gate metal and a second top surface of the second gate metal are planar.

2. The integrated circuit structure of claim 1, wherein the first vertical stack of nanoribbons extend at least partially into the first gate spacer and into the second gate spacer.

3. The integrated circuit structure of claim 1, wherein the second vertical stack of nanoribbons extend at least partially into the first gate spacer and into the second gate spacer.

4. The integrated circuit structure of claim 1, wherein the first wall, the second wall, and the third wall are substantially perpendicular to the first gate spacer or to the second gate spacer.

5. The integrated circuit structure of claim 1, wherein the first gate metal includes an N-type workfunction metal and wherein the second gate metal includes a P-type workfunction metal.

6. The integrated circuit structure of claim 1, wherein the first top surface of the first gate metal and the second top surface of the second gate metal are substantially in a same plane.

7. The integrated circuit structure of claim 1, wherein a top of the first wall, a top of the second wall, a top of the third wall, the first top surface of the first gate metal, and the second top surface of the second gate metal are substantially in a same plane.

8. The integrated circuit structure of claim 1, wherein a top of the first wall, a top of the second wall, and a top of the third wall are in a first plane, wherein the first top surface of the first gate metal and the second top surface of the second gate metal are in a second plane, and wherein the second plane is below the first plane with respect to the gate bottom.

9. The integrated circuit structure of claim 1, wherein the first gate metal completely surrounds each of the first vertical stack of nanoribbons, and wherein the second gate metal completely surrounds each of the second vertical stack of nanoribbons.

10. The integrated circuit structure of claim 1, wherein the first wall, the second wall, and the third wall include a selected one or more of: silicon, nitrogen, carbon, oxygen, hafnium, SinN, SiC, SiON, SiCN, HfO or HfN.

11. The integrated circuit structure of claim 1, wherein the first top surface of the first gate metal includes a layer of the second gate metal.

12. The integrated circuit structure of claim 1, wherein a width of each of the first vertical stack of nanoribbons or a width of each of the second vertical stack of nanoribbons is greater than 25 nm.

13. An integrated circuit structure comprising:
a bottom layer;
a first epitaxial structure on the bottom layer and between a first gate spacer and a second gate spacer;
a second epitaxial structure on the bottom that extends from the first gate spacer to the second gate spacer;
a first wall extending from the bottom layer and between the first gate spacer and the second gate spacer, wherein the first wall separates the first epitaxial structure and the second epitaxial structure from each other;
a second wall extending from the bottom layer and between the first gate spacer and the second gate spacer, wherein the first epitaxial structure is between the second wall and the first wall;
a third wall extending from the bottom layer and between the first gate spacer and the second gate spacer, wherein the second epitaxial structure is between the third wall and the first wall; and
wherein a first top surface of the first epitaxial structure and a second top surface of the second epitaxial structure are planar.

14. The integrated circuit structure of claim 13, wherein the first top surface of the first epitaxial structure and the second top surface of the second epitaxial structure are in a same plane.

15. The integrated circuit structure of claim 14, wherein a top of the second wall and a top of the third wall are in the same plane.

16. The integrated circuit structure of claim 15, wherein a top of the first wall is in the same plane.

17. The integrated circuit structure of claim 13, further comprising:
a first vertical stack of nanoribbons within the first gate spacer;
a second vertical stack of nanoribbons within the second gate spacer; and
wherein the first epitaxial structure is directly coupled with a portion of the first vertical stack of nanoribbons, and wherein the second epitaxial structure is directly coupled with a portion of the second vertical stack of nanoribbons.

18. The integrated circuit structure of claim 13, wherein the first epitaxial structure is a P-type epitaxial structure, and the second epitaxial structure is an N-type epitaxial structure.

19. The integrated circuit structure of claim 13, further comprising a terminal contact above the first wall, wherein the terminal contact is between the second wall and the third wall, and wherein the terminal contact is electrically coupled with the first epitaxial structure and electrically coupled with the second epitaxial structure.

20. The integrated circuit structure of claim 13, further comprising a first terminal contact on the first epitaxial structure and a terminal contact on the second epitaxial structure, wherein the first terminal contact is between the second wall and the first wall, wherein the second terminal contact is between the third wall and the first wall, and wherein the first terminal contact and the second terminal contact are electrically isolated from each other.

21. The integrated circuit structure of claim 13, wherein the first wall, the second wall, or the third wall extend above the first top surface of the first epitaxial structure or the second top surface of the second epitaxial structure.

22. A method comprising:
providing an integrated circuit structure, wherein the integrated circuit structure includes:
a gate bottom,
a first gate spacer and a second gate spacer on the gate bottom,
a first vertical stack of nanoribbons above the gate bottom, wherein each of the first vertical stack of nanoribbons extend from the first gate spacer to the second gate spacer,
a second vertical stack of nanoribbons above the gate bottom, wherein each of the second vertical stack of nanoribbons extend from the first gate spacer to the second gate spacer,
a first wall extending from the gate bottom, a second wall extending from the gate bottom, and a third wall extending from the gate bottom, wherein the first wall is between the first vertical stack of nanoribbons, the first vertical stack of nanoribbons is between the first wall and the second wall, and the second vertical stack of nanoribbons is between the first wall and the third wall;
placing a first gate metal around the first vertical stack of nanoribbons, wherein a top surface of the first gate metal is substantially planar; and
placing a second gate metal around the second vertical stack of nanoribbons, wherein a second top surface of the second gate metal is substantially planar.

23. The method of claim 22, wherein placing the second gate metal around the second vertical stack of nanoribbons further includes:
placing the first gate metal around the second vertical stack of nanoribbons;
removing the first gate metal around the second vertical stack of nanoribbons; and
placing the second gate metal around the second vertical stack of nanoribbons.

24. The method of claim 23, wherein removing the first gate metal around the second vertical stack of nanoribbons further includes applying a wet etch to the first gate metal around the second vertical stack of nanoribbons.

25. The method of claim 22, wherein the first gate metal is a N-type gate metal, and wherein the second gate metal is a P-type gate metal.
